(19) United States
(12) Patent Application Publication
(10) Pub. No.: US 2008/0094152 A1
(43) Pub. Date: Apr. 24, 2008

(54) Modifiable Electrical Component, And Method For Modifying The Component

(76) Inventor: Ivan Hofsajer, Edenvale (ZA)

Correspondence Address: STAAS & HALSEY LLP, SUITE 700, 1201 NEW YORK AVENUE, N.W., WASHINGTON, DC, 20005, US

(21) Appl. No.: 11/795,690

(22) PCT Filed: Dec. 20, 2005
(86) PCT No.: PCT/EP05/56972

§ 371 Date: Jul. 20, 2007

(30) Foreign Application Priority Data
Jan. 20, 2005 (DE) 10 2005 002 797.0

(51) Int. Cl. H03H 7/01

(52) U.S. Cl. 333/174

(57) ABSTRACT

At least one electrical component unit, at least one capacitance structure, at least one induction structure, and at least one electrical connection network are included in a modifiable electrical component. The capacitance structure has a first electrode, at least one other electrode, and at least one dielectric arranged between the electrodes. The induction structure includes a magnetic core having a core inner region in which the capacitance structure is at least partially arranged. The connection network has a connection configuration for the electrical contacting of the electrodes that is modifiable and thus, the entire electrical component is reconfigurable. Different electromagnetic functions can be performed or interconverted based on a single component structure, by modifying the connection configuration.

### CROSS REFERENCE TO RELATED APPLICATIONS

This application is based on and hereby claims priority to German Application No. 10 2005 002 797.0 filed on Jan. 20, 2005, the contents of which are hereby incorporated by reference.

### BACKGROUND

Described below is an electrical component with at least one electrical component unit having at least one capacitance structure, at least one induction structure and at least one electrical connection network. The capacitance structure has a first electrode, at least one further electrode and at least one dielectric arranged between the electrodes. The induction structure has a magnetic core having a core interior space in which the capacitance structure is at least partially arranged and the connection network provides a particular connection configuration for electrically contacting the electrodes of the capacitance structure. A method for modifying the electrical component is furthermore provided.

An electrical component of the type is known for example from Hofsajer et al., IEEE PESC 1998, pages 1957-1963. The component is an integrated capacitance-induction structure. The electrodes and the dielectric of the capacitance structure are arranged to form a multilayer capacitor. The multilayer capacitor lies in the core interior space of a magnetic core. The dielectric of the capacitor is a ceramic. A magnetic material of the magnetic core is a ferrite.

The connection network for electrically contacting the electrodes of the capacitance structure of the known electrical component is fixed for a particular electromagnetic function, which is intended to be produced with the aid of the component. For example, the connection configuration of the connection network is organized so that a parallel or series tuned circuit is produced as the electromagnetic function of the component.

With the aid of the known electrical component, a particular electromagnetic function can respectively be produced with the same component structure via a particular connection configuration of the connection network.

### SUMMARY

An aspect is to provide an electrical component which is more flexible than is known in the art.

An electrical component is provided comprising at least one electrical component unit having at least one capacitance structure, at least one induction structure and at least one electrical connection network, wherein the capacitance structure comprises an electrode, at least one further electrode and at least one dielectric arranged between the electrodes, the induction structure comprises a magnetic core having a core interior space in which the capacitance structure is at least partially arranged and the connection network comprises a particular connection configuration for electrically contacting the electrodes of the capacitance structure. The component is wherein the connection configuration is modifiable.

A method for modifying the electrical component is also provided, wherein a modification of the connection configuration is carried out.

It is fundamental that the connection configuration of the component is modifiable. Various electromagnetic functions can therefore be produced or converted into one another in a straightforward way. The component is multifunctional.

In particular, the electrode comprises a first electrode terminal and at least one second electrode terminal and the further electrode comprises a first further electrode terminal and at least one second further electrode terminal, the electrical contacting of the electrodes taking place via the electrode terminals. Depending on the electromagnetic function to be produced, particular electrode terminals are selected and are connected with the aid of the connection network. The electrical connections between the electrode terminals and/or to the electrode terminals can be removed. Removal of one of the connections can be carried out without destroying the ability to make an electrical connection. This is done, for example, by using electrical switches as electrical connection means.

In a particular embodiment, the electrodes and the dielectric arranged between the electrodes form a plate capacitor. The plate capacitor preferably comprises a multilayer design. This means that a plurality of first layers, a plurality of second layers and layers of dielectric material arranged between them are provided. In this way, the capacitance of the capacitor is increased.

According to another embodiment, the electrodes are arranged mutually parallel. The electrodes form, for example, a coaxial cable which is arranged in the core interior space of the induction unit.

According to another embodiment, a number of component units are provided. Besides the component unit, at least one further component unit is provided. Individual constituents of the component units may be formed by common constituents. A common constituent is, for example, a common magnetic core. It is also conceivable for the common constituent to be formed by common electrodes.

The arrangement of the various component units with respect to one another may be selected arbitrarily. Preferably, when using common components, the arrangement is selected so that space-saving and efficient connection is possible between the component units. For example, when using a common magnetic core, the component units are arranged above one another.

According to a particular embodiment of the method, nodes are created or removed between the electrode terminals of the electrodes of the capacitance structure in order to modify the connection configuration. Electrical switches are preferably used for creating and removing the nodes. The electrical switches may be manipulated by hand.

A data processing program is preferably used for modifying the connection configuration. This means that the configuration of the connection network can be modified with the aid of a data processing program. The electrical component is programmable. For example, the switches for creating and removing nodes are driven with the aid of the data processing program.

In particular, a component is achievable which has an electromagnetic function selected from the group capacitance, inductance, connection line, tuned circuit and/or filter, depending on the connection configuration of the connection network. The functions may readily be converted into one another by modifying the connection configuration.

The configuration of the connection network may be set up before first use of the component. In a particular configuration, the connection configuration is carried out during an operating phase of the component, i.e. after first use of the component.

In summary, the following substantial advantages are provided:
A multifunctional electrical component is provided. A multiplicity of electromagnetic functions can be achieved with a single electrical component.
The multifunctional electrical component is flexible. The various electromagnetic functions of the component can readily be converted into one another by modifying the connection configuration of the connection network.

### BRIEF DESCRIPTION OF THE DRAWINGS

These and other objects and advantages will become more apparent and more readily appreciated from the following description of exemplary embodiments, taken in conjunction with the accompanying drawings which are schematic and do not represent images which are true to scale and of which:

FIG. 1 shows an electrical component unit of the electrical component in a perspective representation.

FIG. 2 shows the component unit indicated in FIG. 1 in a lateral cross section.

FIG. 3 shows an electrical component having two electrical component units in a plan view.

FIGS. 4A, 5A, 6A, 7A, 8A, 9A, 10A, 11A, 12A and 13A show the component unit of FIG. 1 in lateral cross section with different connection configurations of the connection network.

FIGS. 4B, 5B, 6B, 7B, 8B, 9B, 10B, 11B, 12B and 13B show the equivalent circuit diagrams associated with the connection configurations according to FIGS. 4a to 13a.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

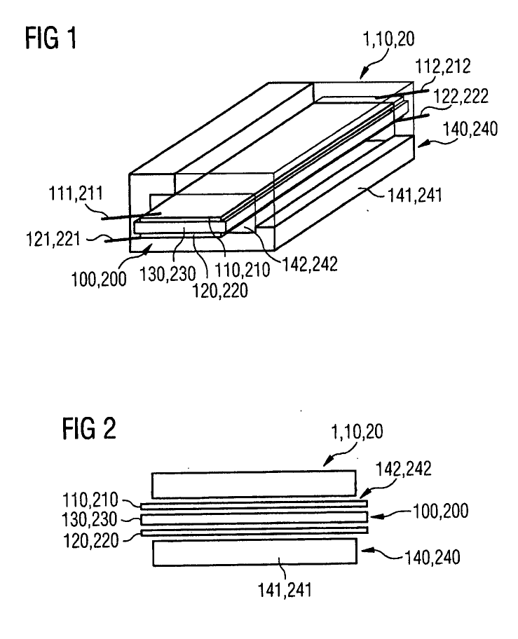

According to the exemplary embodiments described below, an integrated, modifiable i.e. reconfigurable electrical component 1 is provided. An essential constituent of the electrical component 1 is at least one component unit 10. The component unit 10 comprises a capacitance structure 100, an induction structure 140 and a connection network 150 (FIGS. 1 and 2).

The capacitance structure 100 of the component unit 10 comprises an electrode 110, a further electrode 120 and a dielectric 130 arranged between the electrodes 110 and 120. The dielectric 130 of the capacitance structure 100 is formed by a ceramic plate. The electrodes 110 and 120 of the capacitance structure 100 are formed by metallizations, which are applied onto the two main surfaces of the ceramic plate. The capacitance structure 100 is in the form of a plate capacitor.

Each of the electrodes 110 and 120 of the capacitance structure 100 has at least two electrode terminals. The electrode 110 comprises a first electrode terminal 111 and a second electrode terminal 112. The further electrode 120 comprises a first further electrode terminal 121 and a second further electrode terminal 122.

The induction structure 140 of the component unit 10 comprises a magnetic core 141 having a core interior space 142. The core 141 comprises a ferrite as magnetic material.

The capacitance structure 100 is located at least partially in the core interior space 142 of the core 141.

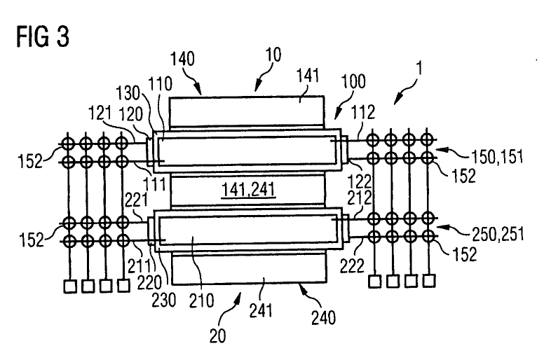

An electrical connection network 150 is provided for electrically contacting the electrodes 110 and 120 of the capacitance structure 100 (cf. FIG. 3). The electrode terminals 111 and 112 of the electrode 110 and the further electrode terminals 121 and 122 of the further electrode 120 are electrically contacted via the connection network 150. The electrical connection network 150 comprises a connection configuration 151. The electrical contactings of the electrode terminals 111, 112, 121 and 122 are fixed by the connection configuration 151.

The connection network 150 is designed so that the connection configuration 151 can be modified and therefore reconfigured. To this end, nodes 152 can be created or removed between the electrode terminals 111, 112, 121 and 122. The nodes 152 can be created or removed without individual connection elements having to be made or destroyed. To this end, the nodes 152 are created using electrical switches (not shown). The electrical switches can be driven electrically via a data processing program.

According to another embodiment, a further component unit 20 is provided in addition to the component unit 10 (FIG. 3). The further component unit 20 has an identical structure to the component unit 10. This means that the further component unit 20 comprises a further capacitance structure 200, a further induction structure 240 and a further connection network 250.

The further capacitance structure 200 comprises an electrode 210 having a first electrode terminal 211 and a second electrode terminal 212, a further electrode 220 having a first further electrode terminal 221 and a second further electrode terminal 222 and a further dielectric 230 arranged between the electrodes 210 and 220.

The further induction structure 240 of the further component unit 20 comprises a further magnetic core 241 having a further core interior space 242. The further core 241 likewise comprises a ferrite as magnetic material. The further capacitance structure 200 is located at least partially in the further core interior space 242 of the further core 241.

The electrode terminals 211, 212, 221 and 222 of the electrodes 210 and 220 of the further component unit 20 are electrically contacted via the further connection network 250, which is based on the further connection configuration 251. The contacting is fixed by the further connection configuration 251. The further connection configuration 251 is also modifiable.

The component units 10 and 20 are arranged on one another and connected to one another so that the magnetic core 141 of the induction structure 140 of the component unit 10 and the further magnetic core 241 of the further induction structure 240 of the further component unit 20 form a common magnetic core (FIG. 3). The connection networks 150 and 250 are also connected to one another so as to provide an entire connection network. The connection configuration of the entire connection network can be modified—like the individual connection networks 150 and 250. An entire reconfigurable connection network is provided.

Other embodiments are obtained by providing more than two of the component units described above.

According to a first embodiment, the connection configuration 151 of the connection network 150 and the connection configuration 251 of the further connection network 250 are respectively fixed before first use of the component 1. On the basis of the connection configurations 151 and 251, respectively, nodes 152 and 252 are created or removed between the electrode terminals 111, 112, 121, 122, 211, 212, 221 and/or 222 or to the electrode terminals 111, 112, 121, 122, 211, 212, 221 and/or 222.

According to another embodiment, the connection configurations 151 and 152 are modified during an operating phase of the component 1, i.e. after first use of the component 1.

Electrical switches, which are driven with the aid of a data processing program, are used for creating or removing the nodes 151 and 152 in both the cases.

Various connection configurations 151 for the connection network 150 of the component unit 10 will be specified below. An electrical component 1 having an individual electromagnetic function is respectively produced by the different connection configurations 151. Merely by modifying the connection configuration 151 of the connection network 150, the individual electromagnetic functions can be converted into one another.

The following examples are respectively restricted to a single component unit, and may be adapted accordingly for an arbitrary number of component units coupled to one another.

### Example 1

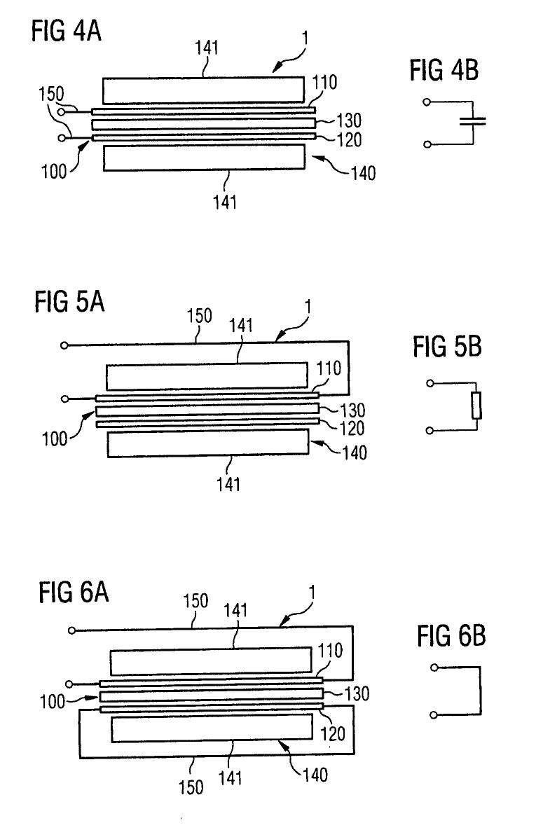

The connection configuration 151 of the component unit 10 is designed so that the electrical component 1 fulfills the electromagnetic function of a capacitor (FIGS. 4A and 4B).

### Example 2

The electrical component 1 is designed to form an inductor. To this end, the electrode 110 together with the electrode terminals 111 and 112 and the connection network 150 form a coil coupled to the magnetic core 141 (FIGS. 5A and 5B).

### Example 3

In addition to the design according to the previous example with the coil, the further electrode terminals 121 and 122 of the further electrode 120 of the capacitance structure 100 are electrically short-circuited (FIGS. 6A and 6B).

### Example 4

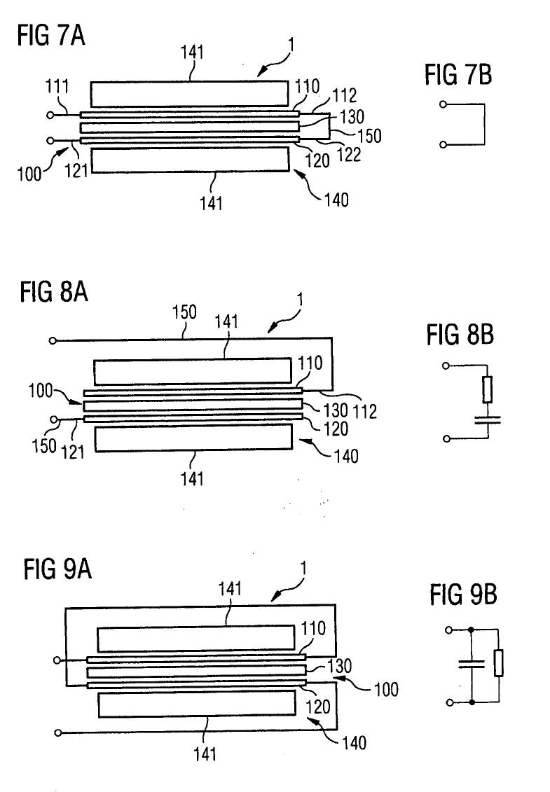

The second electrode terminal 112 of the electrode 110 and the second further electrode terminal 122 of the further electrode 120 are electrically short-circuited via the connection network 150. The electrodes 110 and 120 and the connection network 150 form an electrical connection line (FIGS. 7A and 7B).

### Example 5

The connection configuration 151 of the connection network 150 is designed so that the component 1 functions as a series tuned electrical circuit (FIGS. 8A and 8B).

### Example 6

The selected connection configuration 151 of the connection network leads to a component 1 designed as a parallel tuned electrical circuit (FIGS. 9A and 9B).

### Example 7

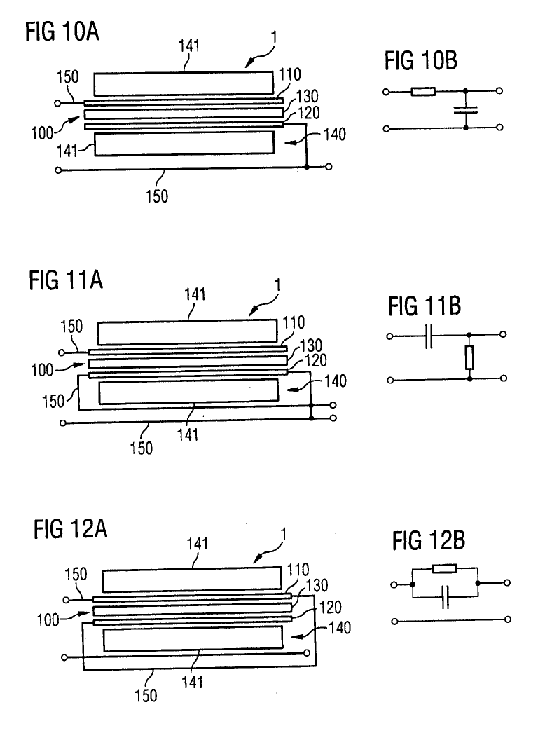

Via the layout of the connection configuration 151, the component is designed as a “lowpass filter” (FIGS. 10A and 10B).

### Example 8

In contrast to the previous example; a “highpass filter” is produced with the electrical component 1 merely by adjusting the connection configuration (FIGS. 11A and 11B).

### Example 9

The electrical component 1 is designed to form a “bandstop filter” (FIGS. 12A and 12B).

### Example 10

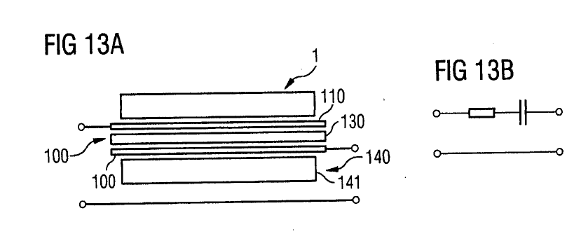

The electrical component is arranged to form a “bandpass filter” (FIGS. 13A and 13B).

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-11. (canceled)

12. An electrical component having at least one electrical component unit, comprising:
at least one capacitance structure having a first electrode, at least one additional electrode and at least one dielectric arranged between the electrodes;
at least one induction structure, each including a magnetic core having a core interior space in which a corresponding one of the at least one capacitance structure is at least partially arranged; and
at least one electrical connection network providing a modifiable connection configuration electrically contacting the electrodes of the capacitance structure.

13. The component as claimed in claim 12, wherein for each corresponding capacitance and induction structure, the first electrode includes a first electrode terminal and at least one second electrode terminal and the additional electrode includes a third electrode terminal and at least one fourth electrode terminal, with each of the first, at least one second, third and at least one fourth electrodes are coupled to one of said at least one electrical connection network corresponding thereto.

14. The component as claimed in claim 13, wherein the first electrode, at least one additional electrode and the at least one dielectric of each capacitance structure form a plate capacitor.

15. The component as claimed in claim 14, wherein the plate capacitor comprises a multilayer design.

16. The component as claimed in claim 15, wherein the first electrode and at least one additional electrode of each of the at least one capacitance structure are arranged mutually parallel in the core interior space.

17. The component as claimed in claim 16, wherein multiple component units are provided.

18. The component as claimed in claim 17, wherein the component has an electromagnetic function including at least one of capacitance, inductance, connection line, tuned circuit and filter, depending on the modifiable connection configuration of the connection network.

19. A method for modifying the electrical component as claimed in claim 12, comprising:
modifying the connection configuration of the connection network.

20. The method as claimed in claim 19, wherein said modifying includes at least one of creating and removing at least one node between electrode terminals of the first electrode and at least one additional electrode of the at least one capacitance structure.

21. The method as claimed in claim 20, wherein said modifying is performed by a data processing program.

22. The method as claimed in claim 21, wherein said modifying of the connection configuration is carried out during an operating phase of the electrical component.
